(19) United States
(12) Patent Application Publication
(10) Pub. No.: US 2024/0319454 A1
(43) Pub. Date: Sep. 26, 2024

(54) SEMICONDUCTOR PACKAGE

(71) Applicant: SAMSUNG ELECTRONICS CO., LTD., Suwon-si (KR)

(72) Inventor: Junghoon Kang, Suwon-si (KR)

(21) Appl. No.: 18/611,499

(22) Filed: Mar. 20, 2024

(30) Foreign Application Priority Data
Mar. 24, 2023 (KR) 10-2023-0039219
May 30, 2023 (KR) 10-2023-0069450

(51) Int. Cl. G02B 6/42; H01L 23/00; H01L 23/498; H01L 25/065

(52) U.S. Cl. CPC G02B 6/4219; G02B 6/4206; H01L 23/49822; H01L 24/08; H01L 24/16; H01L 25/0652; H01L 2224/08146; H01L 2224/08155; H01L 2224/16104; H01L 2224/16157; H01L 2924/0665; H01L 2924/13091; H01L 2924/182

(57) ABSTRACT

Provided is a semiconductor package including a printed circuit board including a cavity extending inward from an upper surface thereof, an optical waveguide extending onto the cavity along the upper surface of the printed circuit board, a first semiconductor chip positioned inside the cavity and including a photonic integrated circuit overlapping a portion of the optical waveguide in a vertical direction, an interposer on the first semiconductor chip, and a second semiconductor chip on the interposer.

### CROSS-REFERENCE TO RELATED APPLICATION

This application claims priority under 35 U.S.C. § 119 to Korean Patent Application Nos. 10-2023-0039219, filed on Mar. 24, 2023, and 10-2023-0069450, filed on May 30, 2023, in the Korean Intellectual Property Office, the disclosures of which are incorporated by reference herein in their entireties.

### TECHNICAL FIELD

The present disclosure relates to a semiconductor package, and more particularly, to a semiconductor package including a photonics chip.

### BACKGROUND

A semiconductor package may include various integrated circuits, such as a memory chip and a logic chip, mounted on a package substrate. To address recent demands on data traffic in data centers and communication infrastructure, research into increasing integration density in semiconductor packages including a photonics chip has been conducted.

### SUMMARY

The present disclosure provides a semiconductor package having a photonics chip mounted therein without a separate printed circuit board.

The present disclosure also provides a semiconductor package with a high degree of integration.

In addition, the problems to be solved by the technical idea of the present disclosure are not limited to the problems mentioned above, and the other problems could be clearly understood by those of ordinary skill in the art from the description below.

According to an aspect of the inventive concept, there is provided a semiconductor package including a printed circuit board including a cavity extending inward from an upper surface thereof, an optical waveguide extending onto the cavity along the upper surface of the printed circuit board, a first semiconductor chip positioned inside the cavity and including a photonic integrated circuit overlapping a portion of the optical waveguide in a vertical direction, an interposer on the first semiconductor chip, and a second semiconductor chip on the interposer.

In general, innovative aspects of the subject matter described in this specification can be embodied in a semiconductor packing including: a main printed circuit board including at least one cavity extending inward from an upper surface thereof, a plurality of main optical waveguides extending onto the at least one cavity along the upper surface of the printed circuit board, a plurality of first semiconductor chips positioned inside the at least one cavity to each overlap a portion of one of the plurality of main optical waveguides in a vertical direction and including an active surface and an inactive surface, an interposer on the plurality of first semiconductor chips, and a second semiconductor chip on the interposer, wherein the interposer overlaps at least a portion of each of the plurality of first semiconductor chips in the vertical direction, and the plurality of first semiconductor chips are mounted inside the at least one cavity such that the active surface faces the interposer.

Another general aspect can be embodied in a semiconductor package that includes: including a printed circuit board including a cavity extending inward from an upper surface thereof, an optical waveguide extending onto the cavity along the upper surface of the printed circuit board, a first semiconductor chip positioned inside the cavity and including a photonic integrated circuit overlapping a portion of the optical waveguide above the cavity in a vertical direction, an interposer on the first semiconductor chip, and a second semiconductor chip on the interposer, wherein the photonic integrated circuit includes a light-receiving section configured to receive an optical signal discharged from the optical waveguide and is configured to convert the optical signal into an electrical signal, the first semiconductor chip is inside the cavity such that the photonic integrated circuit is separated from a bottom surface of the cavity, and at least a portion of the optical waveguide is between the interposer and the first semiconductor chip.

### BRIEF DESCRIPTION OF THE DRAWINGS

FIG. 1 is a perspective view schematically illustrating an example of a semiconductor package.

FIG. 2 is a top view schematically illustrating the semiconductor package of FIG. 1;

FIG. 3 is a cross-sectional view schematically illustrating the semiconductor package of FIG. 1;

FIG. 4 is a magnified view of a region IV of FIG. 3;

FIG. 5 is a top view schematically illustrating an example of a semiconductor package.

FIG. 6 is a top view schematically illustrating an example of a semiconductor package.

FIG. 7 is a perspective view schematically illustrating an example of a semiconductor package.

FIG. 8 is a top view schematically illustrating the semiconductor package of FIG. 7.

FIG. 9 is a cross-sectional view schematically illustrating the semiconductor package of FIG. 7.

### DETAILED DESCRIPTION

The present disclosure may allow various kinds of change or modification and various changes in form, and some examples are illustrated in drawings and described in detail. However, it is not intended that the examples are limited to a specific disclosing form.

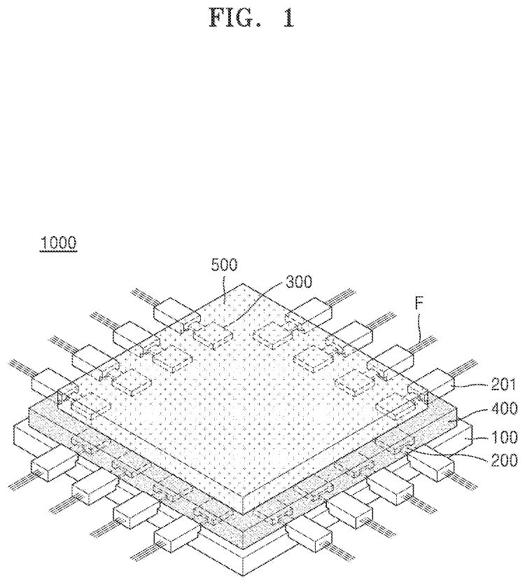

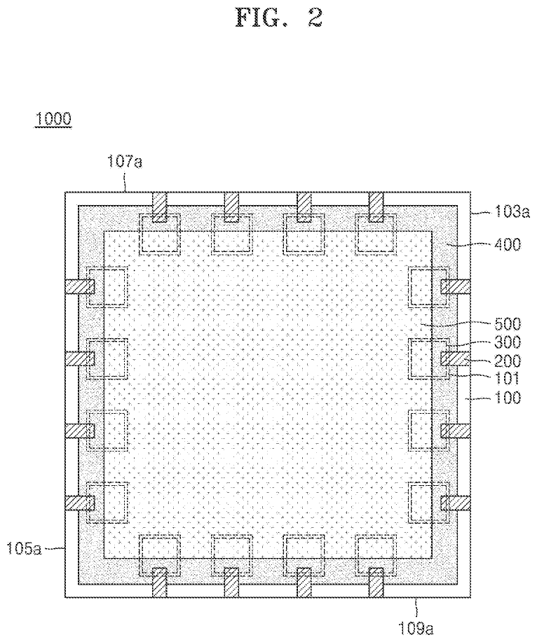

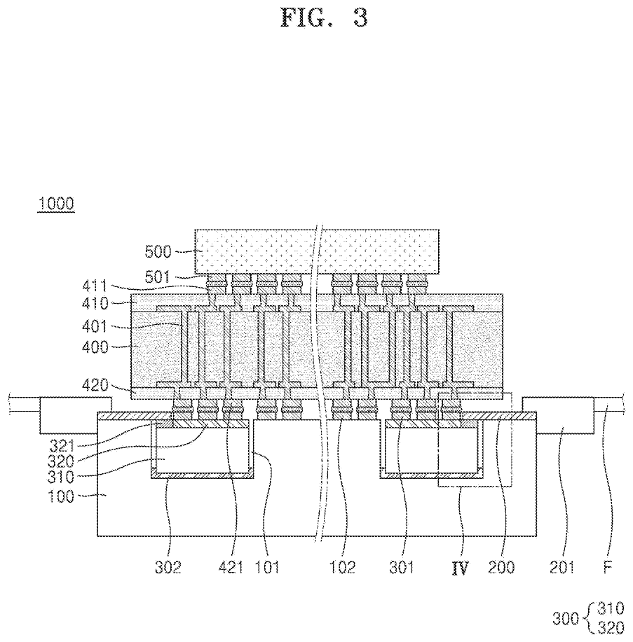

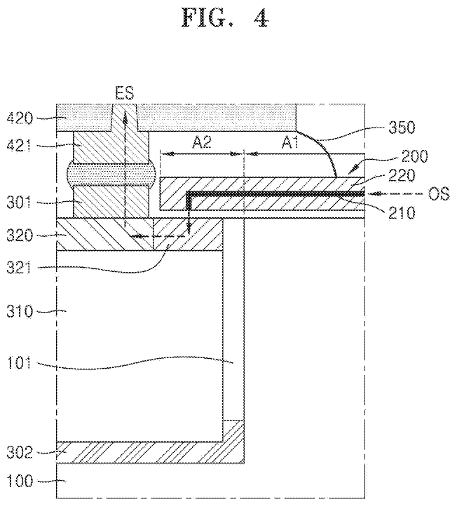

FIG. 1 is a perspective view schematically illustrating an example of a semiconductor package 1000. FIG. 2 is a top view schematically illustrating the semiconductor package 1000 of FIG. 1. FIG. 3 is a cross-sectional view schematically illustrating the semiconductor package 1000 of FIG. 1. FIG. 4 is a magnified view of a region IV of FIG. 3.

Referring to FIGS. 1 to 4, the semiconductor package 1000 may include a printed circuit board 100, an optical waveguide 200, a first semiconductor chip 300, an interposer 400, and a second semiconductor chip 500.

The printed circuit board 100 of the semiconductor package 1000 may include at least one material selected from among a phenol resin, an epoxy resin, and polyimide. For example, the printed circuit board 100 may include at least one material selected from among polyimide, flame retardant 4 (FR-4), tetrafunctional epoxy, polyphenylene ether, epoxy/polyphenylene oxide, bismaleimide triazine (BT), Thermount, cyanate ester, and a liquid crystal polymer.

The printed circuit board 100 may include contact pads 102 on the upper and lower surfaces thereof. The contact pads 102 may be a portion of a circuit wiring patterned after coating a copper (Cu) foil on the upper and lower surfaces of the printed circuit board 100. Particularly, the contact pads 102 may be a region of the circuit wiring exposed to the outside due to the contact pads 102 not being covered by a solder resist layer.

In some implementations, each of the contact pads 102 may include Cu, nickel (Ni), stainless steel, or beryllium copper (BeCu). Internal contact terminals electrically connecting to the contact pads 102 may be formed in the printed circuit board 100. Although FIG. 3 shows that the contact pads 102 of the printed circuit board 100 are on the upper surface of the printed circuit board 100, the contact pads 102 are not limited thereto and may be on the upper and lower surfaces of the printed circuit board 100.

The printed circuit board 100 may have at least one cavity 101. A cavity 101 may extend inward from the upper surface of the printed circuit board 100. The cavity 101 may have a shape in which a portion of the upper surface of the printed circuit board 100 is recessed. In some implementations, the cavity 101 may be separated from an edge of the printed circuit board 100, e.g., only extend partially through the printed circuit board 100. In some implementations, the cavity 101 may be separated from a side surface of the printed circuit board 100.

In some implementations, the size of the cavity 101 may correspond to the size of the first semiconductor chip 300. In some implementations, the height of the cavity 101 may correspond to the height of the first semiconductor chip 300.

The optical waveguide 200 of the semiconductor package 1000 may be attached to the upper surface of the printed circuit board 100. For example, the optical waveguide 200 may extend toward the cavity 101 from one edge of the upper surface of the printed circuit board 100. The optical waveguide 200 may extend onto the cavity 101 of the printed circuit board 100 along the upper surface of the printed circuit board 100. For example, one end of the optical waveguide 200 may be connected to a socket 201 and the other end of the optical waveguide 200 may be on the first semiconductor chip 300.

One surface of the optical waveguide 200 may have a portion in contact with the printed circuit board 100 and the other portion facing the first semiconductor chip 300. That is, the printed circuit board 100 and the first semiconductor chip 300 may be at one side of the optical waveguide 200. Particularly, the lower surface of the optical waveguide 200 may be divided into a first area A1 and a second area A2. The optical waveguide 200 may be in contact with the printed circuit board 100 in the first area A1 and be above the cavity 101 by being separated from the printed circuit board 100 in the second area A2. For example, the optical waveguide 200 may face a light-receiving section of a photonic integrated circuit 321 of the first semiconductor chip 300 in the second area A2.

In some implementations, the optical waveguide 200 may include a cladding 220 and a core 210. The cladding 220 may surround the core 210. The core 210 may have a relatively large refractive index and the cladding 220 may have a relatively small refractive index. An optical signal OS incident to the core 210 may travel along the core 210 having a large refractive index. The optical signal OS traveling from the core 210 to the cladding 220 may be totally reflected from the cladding 220 due to the refractive index difference between the core 210 and the cladding 220 and travel along the core 210. In some implementations, the optical waveguide 200 may be a glass waveguide.

In some implementations, the cladding 220 of the optical waveguide 200 may be in contact with the upper surface of the printed circuit board 100 and the core 210 may be separated from the printed circuit board 100 with the cladding 220 therebetween. The core 210 may be protected from the outside by the cladding 220, thereby suppressing noise generated in the optical signal OS.

Particularly, an optical fiber cable F may be connected to the socket 201 such that the optical signal OS is incident to the core 210 of the optical waveguide 200. The optical signal OS incident to the core 210 of the optical waveguide 200 may be totally reflected from the boundary surface between the core 210 and the cladding 220 and travel along the core 210. The optical signal OS traveling along the core 210 may be discharged from the optical waveguide 200 and incident to the first semiconductor chip 300. The optical signal OS introduced from the outside of the semiconductor package 1000 through the optical waveguide 200 may be incident to the light-receiving section of the photonic integrated circuit 321 of the first semiconductor chip 300.

In some implementations, the optical waveguide 200 may extend along the upper surface of the printed circuit board 100 such that the optical waveguide 200 extends in a direction parallel to the upper surface of the printed circuit board 100. Accordingly, the traveling direction of the optical signal OS traveling along the core 210 of the optical waveguide 200 may also be parallel to the upper surface of the printed circuit board 100. In some implementations, the optical waveguide 200 may further include a reflective layer at a side adjacent to the first semiconductor chip 300 to change the traveling direction of the optical signal OS. However, the optical waveguide 200 is not limited thereto and may be bent toward the first semiconductor chip 300 to change the traveling direction of the optical signal OS.

The first semiconductor chip 300 of the semiconductor package 1000 may include a device layer 320 and a substrate 310. The substrate 310 may include an active surface and an inactive surface that is opposite to the active surface and the device layer 320 may be on the active surface. The device layer 320 of the first semiconductor chip 300 may include the photonic integrated circuit 321. The photonic integrated circuit 321 may be on the active surface of the substrate 310. The photonic integrated circuit 321 may overlap a portion of the optical waveguide 200 in the vertical direction.

The photonic integrated circuit 321 may receive the optical signal OS and perform computation processing on the optical signal OS to convert the optical signal OS into an electrical signal ES. For example, the photonic integrated circuit 321 of the first semiconductor chip 300 may include the light-receiving section. The light-receiving section may receive the optical signal OS having traveled through the optical waveguide 200.

In some implementations, the photonic integrated circuit 321 may be separated from the optical waveguide 200. Particularly, the light-receiving section of the photonic integrated circuit 321 may be separated from the optical waveguide 200 in the vertical direction. The second area A2 of the optical waveguide 200 may be above the photonic integrated circuit 321 in the vertical direction. The optical signal OS incident on the optical waveguide 200 may be discharged in the second area A2 of the optical waveguide 200 and the optical signal OS discharged in the second area A2 may be incident on the photonic integrated circuit 321.

In some implementations, the device layer 320 of the first semiconductor chip 300 may further include various types of individual devices in addition to the photonic integrated circuit 321. For example, the plurality of individual devices may include various micro electronic devices, e.g., a complementary metal-oxide semiconductor (CMOS) transistor, a metal-oxide-semiconductor field-effect transistor (MOSFET), a system large scale integration (LSI) chip, an image sensor, such as a CMOS imaging sensor (CIS), a micro-electro-mechanical system (MEMS), an active device, and a passive device.

The substrate 310 of the first semiconductor chip 300 may include silicon (Si). However, the material of the substrate 310 is not limited to Si. For example, the substrate 310 may include another semiconductor element, such as germanium (Ge), or a compound semiconductor, such as silicon carbide (SiC), gallium arsenide (GaAs), indium arsenide (InAs), or indium phosphide (InP).

The substrate 310 may a silicon on insulator (SOI) structure. For example, the substrate 310 may include a buried oxide (BOX) layer. In addition, the substrate 310 may include various device isolation structures, such as a shallow trench isolation (STI) structure.

The first semiconductor chip 300 may be mounted inside the cavity 101 of the printed circuit board 100. Particularly, the first semiconductor chip 300 may be mounted inside the cavity 101 such that the device layer 320 is on the substrate 310. That is, the first semiconductor chip 300 may be mounted such that the substrate 310 is in contact with the bottom of the cavity 101 and the device layer 320 is separated from the bottom of the cavity 101. That is, the first semiconductor chip 300 may be mounted inside the cavity 101 such that an active surface of the first semiconductor chip 300 faces the interposer 400.

In some implementations, the first semiconductor chip 300 may further include a connection pad 301 on the active surface of the substrate 310. The connection pad 301 may electrically connect the first semiconductor chip 300 to the interposer 400. Particularly, the connection pad 301 of the first semiconductor chip 300 may be in contact with a lower pad 421 of the interposer 400 to transfer the electrical signal ES discharged from the first semiconductor chip 300 to the lower pad 421 of the interposer 400. That is, the first semiconductor chip 300 may receive the optical signal OS, convert the optical signal OS into the electrical signal ES through computation processing, and transfer the electrical signal ES to the interposer 400.

In some implementations, the substrate 310 may be attached to the bottom surface of the cavity 101 through an adhesive member 302. For example, the adhesive member 302 may include an adhesive film, such as a direct adhesive film (DAF). That is, the first semiconductor chip 300 may be electrically isolated from the bottom surface of the cavity 101 of the printed circuit board 100.

In some implementations, the semiconductor package 1000 may include a plurality of cavities 101 of the printed circuit board 100 and a plurality of first semiconductor chips 300. The plurality of cavities 101 and the plurality of first semiconductor chips 300 may be in a line along the edges of the upper surface of the printed circuit board 100. For example, each of cavities 101 are separated a same distance from their respective closest edge, e.g., edges 103a, 105a, 107a, and 109a.

Although FIG. 2 shows that four cavities 101 and four first semiconductor chips 300 are at each of the edges of the printed circuit board 100, the numbers of cavities 101 and first semiconductor chips 300 are not limited thereto.

The interposer 400 of the semiconductor package 1000 may be on the first semiconductor chip 300. The interposer 400 may be on the first semiconductor chip 300 and the printed circuit board 100. That is, the interposer 400 may be stacked on the first semiconductor chip 300.

The interposer 400 may include a substrate and a through via 401 penetrating into the substrate. For example, the substrate may include glass and the through via 401 may be a through glass via (TGV). However, the substrate and the through via 401 are not limited thereto, and the substrate may include Si and the through via 401 may be a through silicon via (TSV). Although FIG. 3 shows that the through via 401 has a constant width, the through via 401 is not limited thereto and may have a width varying away the first semiconductor chip 300.

The interposer 400 may further include a redistribution structure. The redistribution structure may be on the upper or lower surface of the substrate of the interposer 400. The redistribution structure on the upper surface of the substrate of the interposer 400 is referred to as an upper redistribution structure 410, and the redistribution structure on the lower surface of the substrate of the interposer 400 is referred to as a lower redistribution structure 420.

Each of the upper and lower redistribution structures 410 and 420 may include at least one redistribution insulating layer and a plurality of redistribution patterns. The at least one redistribution insulating layer may include an organic insulating material. For example, the at least one redistribution insulating layer may include a photo imageable dielectric (PID), such as polyimide.

The plurality of redistribution patterns may include a plurality of redistribution lines and a plurality of redistribution vias. The plurality of redistribution patterns may include, for example, a metal, such as copper (Cu), aluminum (Al), tungsten (W), titanium (Ti), tantalum (Ta), indium (In), molybdenum (Mo), manganese (Mn), cobalt (Co), tin (Sn), Ni, magnesium (Mg), rhenium (Re), beryllium (Be), gallium (Ga), or ruthenium (Ru), or an alloy of metals, but are not limited thereto.

A redistribution via and a redistribution line of the upper redistribution structure 410 may be electrically connected to an upper pad 411. A redistribution via and a redistribution line of the lower redistribution structure 420 may be electrically connected to the lower pad 421 of the interposer 400. In some implementations, the electrical signal ES discharged from the first semiconductor chip 300 may be transferred to the second semiconductor chip 500 through the lower redistribution structure 420, the through via 401, and the upper redistribution structure 410.

In some implementations, a portion of the optical waveguide 200 may be under the interposer 400 in the vertical direction. That is, the portion of the optical waveguide 200 may be between the interposer 400 and the first semiconductor chip 300. Because the first semiconductor chip 300 is under the interposer 400, the portion of the optical waveguide 200 on the first semiconductor chip 300 may be under the interposer 400.

In some implementations, the interposer 400 may overlap at least a portion of each of the plurality of first semiconductor chips 300. One side of each of the plurality of first semiconductor chips 300 may be under the interposer 400 and the other side thereof may not overlap the interposer 400 along the vertical direction.

The semiconductor package 1000 may further include a transparent encapsulation material 350 transmitting light therethrough. The transparent encapsulation material 350 may fill an area between the interposer 400 and the first semiconductor chip 300. The transparent encapsulation material 350 may surround the connection pad 301 of the first semiconductor chip 300 and the lower pad 421 of the interposer 400.

In some implementations, the transparent encapsulation material 350 may include epoxy, silicone, polymethyl methacrylate (PMMA), polyethylene, polystyrene, or a combination thereof but generally include epoxy.

In some implementations, the transparent encapsulation material 350 may surround a portion of the optical waveguide 200. The optical waveguide 200 may be separated from the interposer 400 with the transparent encapsulation material 350 therebetween. The transparent encapsulation material 350 may be between the optical waveguide 200 and the interposer 400 while filling an empty space between the interposer 400 and the first semiconductor chip 300. The durability of the semiconductor package 1000 may be improved by the transparent encapsulation material 350.

The second semiconductor chip 500 of the semiconductor package 1000 may be on the interposer 400. The second semiconductor chip 500 may be mounted on the upper surface of the interposer 400. The first semiconductor chip 300, the interposer 400, and the second semiconductor chip 500 may be sequentially stacked on the printed circuit board 100 in the vertical direction.

The second semiconductor chip 500 may include an active surface and an inactive surface that is opposite to the active surface. In some implementations, the second semiconductor chip 500 may include an application specific integrated circuit (ASIC).

In some implementations, the second semiconductor chip 500 may be mounted on the interposer 400 such that the active surface of the second semiconductor chip 500 faces downward. That is, a connection pad 501 of the second semiconductor chip 500 may be on the active surface of the second semiconductor chip 500, and the second semiconductor chip 500 may be mounted on the interposer 400 such that the connection pad 501 is electrically connected to the upper pad 411 of the interposer 400.

In some implementations, various types of individual devices may be on the active surface of the second semiconductor chip 500. For example, the plurality of individual devices may include various micro electronic devices, e.g., a CMOS transistor, a MOSFET, a system LSI chip, an image sensor, such as a CIS, a MEMS, an active device, and a passive device.

In some implementations, the size of the upper surface of the second semiconductor chip 500 may be less than the size of the upper surface of the interposer 400. The second semiconductor chip 500 may cover a portion of the interposer 400. The connection pad 501 of the second semiconductor chip 500 may be electrically connected to the upper pad 411 of the interposer 400. Because the upper pad 411 of the interposer 400 is connected to the upper redistribution structure 410, the second semiconductor chip 500 may be mounted in a fan-out structure with respect to the printed circuit board 100. That is, a distance across the lower pads 421 of the interposer 400 may be greater than a distance across the connection pads 501 of the second semiconductor chip 500. For example, at least some of connection pads 301 of the first semiconductor chip 300 may not overlap the second semiconductor chip 500 in the vertical direction, e.g., be farther to the right or left than the second semiconductor chip 500 in FIG. 3.

In the semiconductor package 1000, the first semiconductor chip 300 may be inside the cavity 101 of the printed circuit board 100 and receive the optical signal OS through the optical waveguide 200 extending onto the cavity 101. Accordingly, the size of the printed circuit board 100 may be small. In addition, the length along which the electrical signal ES converted by the first semiconductor chip 300 is transferred to the second semiconductor chip 500 may be reduced, thereby increasing signal accuracy.

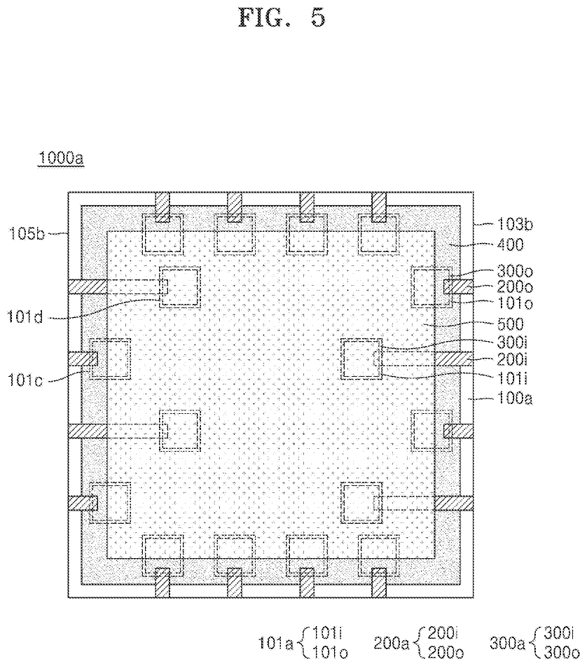

FIG. 5 is a top view schematically illustrating an example of a semiconductor package 1000a.

Referring to FIG. 5, the semiconductor package 1000a may include a printed circuit board 100a, an optical waveguide 200a, a first semiconductor chip 300a, the interposer 400, and the second semiconductor chip 500.

Hereinafter, a description made for the semiconductor package 1000 of FIG. 2 is omitted, and differences between the semiconductor package 1000a of FIG. 5 and the semiconductor package 1000 of FIG. 2 are mainly described.

The printed circuit board 100a of the semiconductor package 1000a may include a plurality of cavities 101a. The plurality of cavities 101a may include a first cavity 101i and a second cavity 101o. The first cavity 101i and the second cavity 101o may be arranged in a zigzag manner along one edge of the printed circuit board 100a.

Particularly, the first cavity 101i and the second cavity 101o may be arranged along the one edge of the printed circuit board 100a. The distance of the first cavity 101i separated from the one edge of the printed circuit board 100a may be different from the distance of the second cavity 101o separated from the one edge of the printed circuit board 100a. In some implementations, the distance of the first cavity 101i separated from the one edge of the printed circuit board 100a may be greater than the distance of the second cavity 101o separated from the one edge of the printed circuit board 100a.

In some implementations, the plurality of cavities 101a may include a plurality of first cavities 101i and a plurality of second cavities 101o which are alternately arranged. That is, when viewing the printed circuit board 100a from the top, the plurality of first cavities 101i and the plurality of second cavities 101o may be alternately arranged such that some of the plurality of cavities 101a are arranged in a zigzag manner along the one edge of the printed circuit board 100a.

In some implementations, the plurality of first cavities 101i and the plurality of second cavities 101o may be arranged along the one edge of the printed circuit board 100a and another edge facing the one edge. That is, the plurality of cavities 101a at the opposing edges 103b and 105b can be arranged in a zigzag manner. For example, the first cavity 101i is positioned further from one edge 103b than the second cavity 101o, which is closer to the one edge 103b. On the other edge 105b facing the one edge 103b, the plurality of cavities can be arranged in a similar, yet opposite way. For example, a first cavity 101c at the opposite edge 105b that is positioned at the same horizontal level (as viewed in FIG. 5) as the first cavity 101i at the one edge 103b is closer to the other edge 105b, and a second cavity 101d at the other edge 105b that is positioned at the same horizontal level (as viewed in FIG. 5) as the second cavity 101o at the one edge 103b is further from the other edge 105b than the first cavity 101c at the other edge 105b. Although FIG. 5 shows that the first cavity 101i and the second cavity 101o are at both edges, the number of edges at which the first cavity 101i and the second cavity 101o are arranged is not limited thereto.

The semiconductor package 1000a may include at least one first semiconductor chip 300a. The at least one first semiconductor chip 300a may be inside the plurality of cavities 101a, respectively. The at least one first semiconductor chip 300a may include an inner semiconductor chip 300i and an outer semiconductor chip 300o. The inner semiconductor chip 300i may be inside the first cavity 101i of the printed circuit board 100a and the outer semiconductor chip 300o may be inside the second cavity 101o of the printed circuit board 100a. Accordingly, the inner semiconductor chip 300i may have a greater distance separated from an edge of the printed circuit board 100a than the outer semiconductor chip 300o. That is, the inner semiconductor chip 300i may be closer to the center of the upper surface of the printed circuit board 100a than the outer semiconductor chip 300o.

The semiconductor package 1000a may include at least one optical waveguide 200a. The at least one optical waveguide 200a may include an inner optical waveguide 200i and an outer optical waveguide 200o. The inner optical waveguide 200i may extend onto the inner semiconductor chip 300i and the outer optical waveguide 200o may extend onto the outer semiconductor chip 300o. That is, the inner optical waveguide 200i may extend onto the first cavity 101i from one edge of the printed circuit board 100a and the outer optical waveguide 200o may extend onto the second cavity 101o of the printed circuit board 100a. Accordingly, the length of the inner optical waveguide 200i may be greater than the length of the outer optical waveguide 200o.

The interposer 400 and the second semiconductor chip 500 of the semiconductor package 1000a may be the interposer 400 and the second semiconductor chip 500 of FIG. 2 described above.

In the semiconductor package 1000a according to the present technical idea, the first semiconductor chip 300a may be inside each of the plurality of cavities 101a arranged in a zigzag manner, thereby suppressing a phenomenon that a short circuit occurs between first semiconductor chips 300a and reducing the size of the printed circuit board 100a.

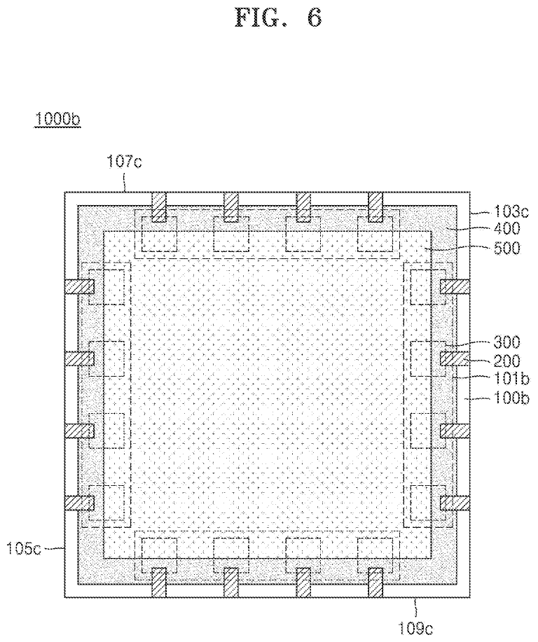

FIG. 6 is a top view schematically illustrating an example of a semiconductor package 1000b.

Referring to FIG. 6, the semiconductor package 1000b may include a printed circuit board 100b, the optical waveguide 200, the first semiconductor chip 300, the interposer 400, and the second semiconductor chip 500.

Hereinafter, a description made for the semiconductor package 1000 of FIG. 2 is omitted, and differences between the semiconductor package 1000b of FIG. 6 and the semiconductor package 1000 of FIG. 2 are mainly described.

The printed circuit board 100b of the semiconductor package 1000b may include at least one cavity 101b. The at least one cavity 101b may be in the upper surface of the printed circuit board 100b. The at least one cavity 101b may have a shape in which a portion of the upper surface of the printed circuit board 100b is recessed.

In some implementations, the plurality of first semiconductor chips 300 may be mounted inside a cavity 101b. That is, at least two first semiconductor chips 300 may be mounted inside one cavity 101b. For example, a plurality of optical waveguides 200 may extend onto one cavity 101b.

In some implementations, one cavity 101b may be at each of the edges of the printed circuit board 100b. For example, each cavity 101b is a same distance from the respective closest edge 103c, 105c, 107c, and 109c. Accordingly, the plurality of first semiconductor chips 300 arranged along one edge of the printed circuit board 100b may be inside one cavity 101b.

In the semiconductor package 1000b according to the present technical idea, the size of the cavity 101b may increase and the number of cavities 101b may decrease, thereby reducing the difficulty of a process. In addition, because there are no partitioning walls isolating cavities 101b from each other, the size of the printed circuit board 100b may be reduced.

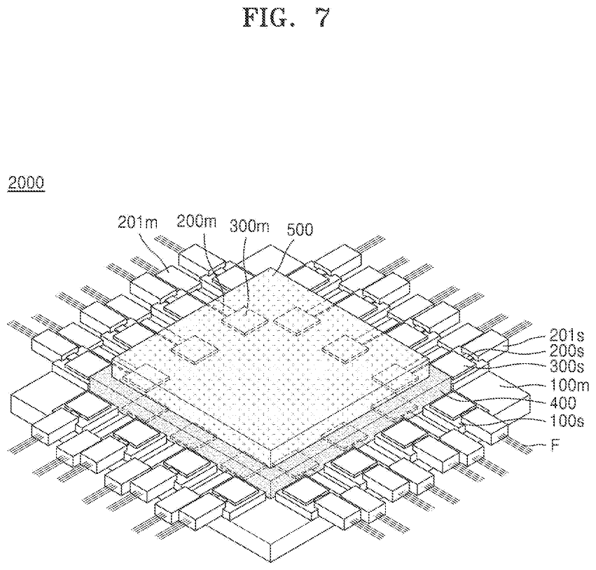

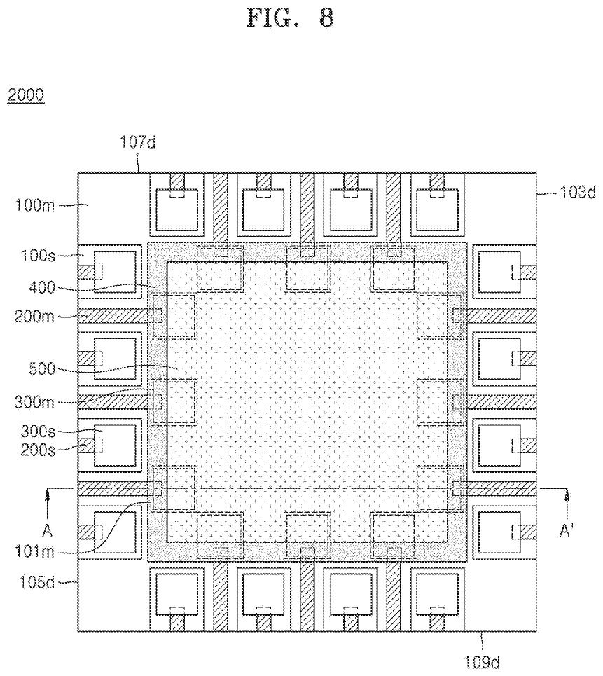

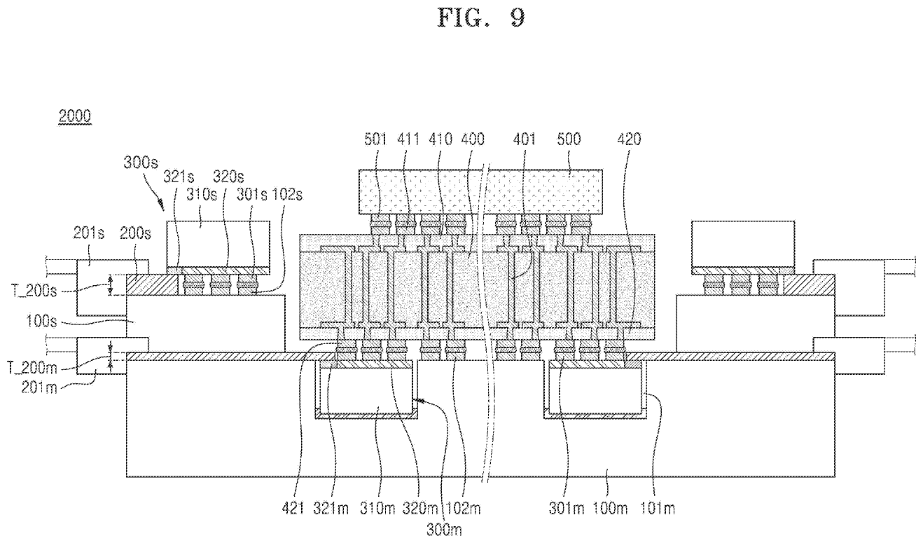

FIG. 7 is a perspective view schematically illustrating a semiconductor package 2000. FIG. 8 is a top view schematically illustrating the semiconductor package 2000 of FIG. 7. FIG. 9 is a cross-sectional view schematically illustrating the semiconductor package 2000 of FIG. 7.

The semiconductor package 2000 may include a main printed circuit board 100m, a sub-printed circuit board 100s, a main optical waveguide 200m, a sub-optical waveguide 200s, a first semiconductor chip 300m, a third semiconductor chip 300s, the interposer 400, and the second semiconductor chip 500.

Hereinafter, a description made for the semiconductor package 1000 of FIG. 1 is omitted, and differences between the semiconductor package 2000 of FIG. 7 and the semiconductor package 1000 of FIG. 1 are mainly described.

The main printed circuit board 100m and the sub-printed circuit board 100s of the semiconductor package 2000 may include at least one material selected from among a phenol resin, an epoxy resin, and polyimide. For example, the main printed circuit board 100m and the sub-printed circuit board 100s may include at least one material selected from among polyimide, FR-4, tetrafunctional epoxy, polyphenylene ether, epoxy/polyphenylene oxide, BT, Thermount, cyanate ester, and a liquid crystal polymer.

The main printed circuit board 100m may include at least one cavity 101m in the upper surface thereof and include contact pads 102m on the upper and lower surfaces thereof. In some implementations, the main printed circuit board 100m may include the printed circuit board 100 of FIG. 1, the printed circuit board 100a of FIG. 5, or the printed circuit board 100b of FIG. 6 described above.

The sub-printed circuit board 100s may be mounted on the upper surface of the main printed circuit board 100m. The upper surface of the sub-printed circuit board 100s may be less than the upper surface of the main printed circuit board 100m. That is, the sub-printed circuit board 100s may be stacked on the upper surface of the main printed circuit board 100m while covering a portion of the main printed circuit board 100m.

In some implementations, the sub-printed circuit board 100s may be mounted on the main printed circuit board 100m such that one side of the sub-printed circuit board 100s is coplanar with one side of the main printed circuit board 100m. In some implementations, the other side of the sub-printed circuit board 100s that is opposite to the one side thereof may be on the main printed circuit board 100m. That is, the sub-printed circuit board 100s may not extend onto a cavity 101m of the main printed circuit board 100m. When viewing the semiconductor package 2000 from the top, the cavity 101m of the main printed circuit board 100m may be more inward of the main printed circuit board 100m the compared the sub-printed circuit board 100s.

In some implementations, the cavity 101m of the main printed circuit board 100m may be under the interposer 400 in the vertical direction and the sub-printed circuit board 100s may be at one side of the interposer 400. Because the sub-printed circuit board 100s and the interposer 400 are mounted on the upper surface of the main printed circuit board 100m, the vertical level of the lower surface of the sub-printed circuit board 100s may be substantially the same as the vertical level of the lower surface of the interposer 400. The term “vertical level” used in the specification indicates a distance separated from the lower surface of the main printed circuit board 100m in the vertical direction.

The sub-printed circuit board 100s may include contact pads 102s on the upper and lower surfaces thereof. Particularly, the contact pads 102s on the lower surface of the sub-printed circuit board 100s may be electrically connected to the contact pads 102m on the upper surface of the main printed circuit board 100m, respectively. The contact pads 102s on the upper surface of the sub-printed circuit board 100s may be electrically connected to connection pads 301s of the third semiconductor chip 300s. That is, the sub-printed circuit board 100s may electrically connect the third semiconductor chip 300s to the main printed circuit board 100m.

Each of the main optical waveguide 200m and the sub-optical waveguide 200s of the semiconductor package 2000 may include a cladding and a core. The cladding may surround the core. The core may have a relatively large refractive index and the cladding may have a relatively small refractive index. An optical signal incident to the core may travel along the core having the large refractive index. In some implementations, the optical waveguide 200 may be a glass waveguide.

The main optical waveguide 200m may be on the upper surface of the main printed circuit board 100m. That is, the vertical level of the upper surface of the main optical waveguide 200m may be substantially the same as the vertical level of the lower surface of the sub-printed circuit board 100s. The main optical waveguide 200m may extend onto the cavity 101m along the upper surface of the main printed circuit board 100m. The main optical waveguide 200m may be connected to a main socket 201m to receive an optical signal and transfer the received optical signal to the first semiconductor chip 300m.

The main printed circuit board 100m and the first semiconductor chip 300m may be at one side of the main optical waveguide 200m. That is, the main printed circuit board 100m and the first semiconductor chip 300m may be at the same side of the main optical waveguide 200m. At least a portion of the main optical waveguide 200m may be between the first semiconductor chip 300m and the interposer 400. In some implementations, the main optical waveguide 200m may be the optical waveguide 200 of FIG. 1 or the optical waveguide 200a of FIG. 5 described above.

The sub-optical waveguide 200s may be on the sub-printed circuit board 100s. The sub-optical waveguide 200s may be connected to a sub-socket 201s to receive an optical signal and transfer the received optical signal to the third semiconductor chip 300s. Because the sub-optical waveguide 200s is on the upper surface of the sub-printed circuit board 100s, the vertical level of the sub-optical waveguide 200s may be higher than the vertical level of the main optical waveguide 200m. In some implementations, the difference between the vertical level of the sub-optical waveguide 200s and the vertical level of the main optical waveguide 200m may be the thickness of the sub-printed circuit board 100s. The term “thickness” used in the specification indicates a length in the vertical direction.

The third semiconductor chip 300s may be mounted on the sub-printed circuit board 100s in a flip-chip manner. That is, the third semiconductor chip 300s may be mounted on the sub-printed circuit board 100s such that a device layer 320s of the third semiconductor chip 300s faces downward. The sub-optical waveguide 200s may be below the third semiconductor chip 300s in the vertical direction and a portion of the sub-optical waveguide 200s may face the device layer 320s of the third semiconductor chip 300s.

A portion of the sub-optical waveguide 200s may be between the sub-printed circuit board 100s and the third semiconductor chip 300s. That is, the sub-printed circuit board 100s may be at one side of the sub-optical waveguide 200s and the third semiconductor chip 300s may be at the other side of the sub-optical waveguide 200s. The sub-optical waveguide 200s may face a photonic integrated circuit 321s of the third semiconductor chip 300s. In some implementations, the sub-optical waveguide 200s may be separated from the photonic integrated circuit 321s of the third semiconductor chip 300s in the vertical direction.

The third semiconductor chip 300s may be separated from the sub-printed circuit board 100s by the connection pads 301s and the contact pads 102s. That is, the photonic integrated circuit 321s of the third semiconductor chip 300s may be separated from the upper surface of the sub-printed circuit board 100s by the thickness of a connection pad 301s of the third semiconductor chip 300s and the thickness of a contact pad 102s of the sub-printed circuit board 100s. Accordingly, a thickness T_200s of the sub-optical waveguide 200s may be greater than a thickness T_200m of the main optical waveguide 200m. In some implementations, the thickness T_200s of the sub-optical waveguide 200s may be greater than the thickness T_200m of the main optical waveguide 200m by the distance between the upper surface of the sub-printed circuit board 100s and the photonic integrated circuit 321s of the third semiconductor chip 300s separated from each other by the contact pad 102s and the connection pad 301s.

The main optical waveguide 200m may be between sub-printed circuit boards 100s. That is, the main optical waveguide 200m may be exposed without being covered by the sub-printed circuit board 100s. For example, as shown in FIG. 8, main optical waveguides 200m and sub-printed circuit boards 100s may be alternately arranged.

The first semiconductor chip 300m of the semiconductor package 2000 may be mounted inside the cavity 101m of the main printed circuit board 100m. In some implementations, each cavity 101m is located a same distance from the closest edge, e.g., edges 103d, 105d, 107d, and 109d. The first semiconductor chip 300m may include a device layer 320m and a substrate 310m. The substrate 310m of the first semiconductor chip 300m may include an active surface and an inactive surface that is opposite to the active surface and the device layer 320m may be on the active surface of the substrate 310m.

In some implementations, a photonic integrated circuit 321m may be in the device layer 320m of the first semiconductor chip 300m. The photonic integrated circuit 321m may receive, by using a light-receiving section thereof, an optical signal discharged from the main optical waveguide 200m and convert the received optical signal into an electrical signal.

The photonic integrated circuit 321m of the device layer 320m of the first semiconductor chip 300m may face the main optical waveguide 200m. That is, the first semiconductor chip 300m may be mounted inside the cavity 101m such that the device layer 320m is on the substrate 310m. That is, the device layer 320m of the first semiconductor chip 300m may be separated from the bottom surface of the cavity 101m with the substrate 310m therebetween. The photonic integrated circuit 321m of the first semiconductor chip 300m may face a portion of the main optical waveguide 200m.

The substrate 310m of the first semiconductor chip 300m may be attached to the bottom surface of the cavity 101m by the adhesive member 302. In some implementations, the adhesive member 302 may include a non-conductive material such that the substrate 310m of the first semiconductor chip 300m is electrically isolated from the main printed circuit board 100m.

The third semiconductor chip 300s of the semiconductor package 2000 may be mounted on the upper surface of the sub-printed circuit board 100s. The third semiconductor chip 300s may include the device layer 320s and a substrate 310s. The device layer 320s of the third semiconductor chip 300s may include the photonic integrated circuit 321s. That is, the third semiconductor chip 300s may include the photonic integrated circuit 321s configured to receive an optical signal and perform computation processing on the received optical signal. For example, the photonic integrated circuit 321s of the third semiconductor chip 300s may include a light-receiving section. The light-receiving section may receive the optical signal having traveled through the sub-optical waveguide 200s.

In some implementations, the device layer 320s of the third semiconductor chip 300s may further include various types of a plurality of individual devices in addition to the photonic integrated circuit 321s. For example, the plurality of individual devices may include various micro electronic devices, e.g., a CMOS transistor, a MOSFET, a system LSI chip, an image sensor, such as a CIS, a MEMS, an active device, and a passive device.

The substrate 310s of the third semiconductor chip 300s may include Si. However, the material of the substrate 310s is not limited to Si. For example, the substrate 310s may include another semiconductor element, such as Ge, or a compound semiconductor, such as SiC, GaAs, InAs, or InP.

In some implementations, the third semiconductor chip 300s may be substantially the same type of semiconductor chip as the first semiconductor chip 300m. However, the type of the third semiconductor chip 300s is not limited thereto.

In some implementations, the third semiconductor chip 300s may further include the connection pads 301s on the device layer 320s. The connection pads 301s may electrically connect the third semiconductor chip 300s to the sub-printed circuit board 100s. Particularly, the connection pads 301s of the third semiconductor chip 300s may be in contact with the contact pads 102s of the sub-printed circuit board 100s such that an electrical signal discharged from the third semiconductor chip 300s is transferred to the second semiconductor chip 500 through the sub-printed circuit board 100s, the main printed circuit board 100m, and the interposer 400.

The interposer 400 of the semiconductor package 2000 may be on the first semiconductor chip 300. The interposer 400 may be at one side of the sub-printed circuit board 100s. The interposer 400 may be electrically connected to the main printed circuit board 100m and the first semiconductor chip 300m through the lower pad 421. Particularly, some of a plurality of lower pads 421 on the lower surface of the interposer 400 may be electrically connected to connection pads 301m of the first semiconductor chip 300m and other some of the plurality of lower pads 421 on the lower surface of the interposer 400 may be electrically connected to contact pads 102m of the main printed circuit board 100m.

An electrical signal transferred from the third semiconductor chip 300s to the main printed circuit board 100m through the sub-printed circuit board 100s may travel to the interposer 400. Conclusively, an electrical signal discharged from each of the first semiconductor chip 300m and the third semiconductor chip 300s may be transferred to the second semiconductor chip 500 through the interposer 400.

The second semiconductor chip 500 may be on the interposer 400. The second semiconductor chip 500 may include an active surface and an inactive surface that is opposite to the active surface. In some implementations, the connection pad 501 may be on the active surface of the second semiconductor chip 500. Because the second semiconductor chip 500 is mounted on the interposer 400 such that the active surface of the second semiconductor chip 500 faces the interposer 400, the upper pad 411 of the interposer 400 may be electrically connected to the connection pad 501 of the second semiconductor chip 500. In some implementations, the connection pad 501 may be on the inactive surface of the second semiconductor chip 500 and the second semiconductor chip 500 may include a through via connected to the connection pad 501. The second semiconductor chip 500 may be mounted on the interposer 400 such that the inactive surface of the second semiconductor chip 500 faces the interposer 400. In some implementations, the second semiconductor chip 500 may be substantially the same as the second semiconductor chip 500 of FIG. 1 described above.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a combination can in some cases be excised from the combination, and the combination may be directed to a subcombination or variation of a subcombination.

While the present disclosure has been particularly shown and described with reference to embodiments thereof, it will be understood that various changes in form and details may be made therein without departing from the spirit and scope of the following claims.

What is claimed is:

1. A semiconductor package comprising:
a printed circuit board defining a cavity extending inward from an upper surface thereof;
an optical waveguide extending above the cavity from the upper surface of the printed circuit board;
a first semiconductor chip positioned inside the cavity and comprising a photonic integrated circuit overlapping a portion of the optical waveguide in a vertical direction;
an interposer on the first semiconductor chip; and
a second semiconductor chip on the interposer.

2. The semiconductor package of claim 1, wherein a lower surface of the optical waveguide is divided into a first area and a second area, the first area contacts the printed circuit board, and the second area is above the cavity and faces a light-receiving section of the photonic integrated circuit.

3. The semiconductor package of claim 2, wherein the photonic integrated circuit is separated from the second area of the optical waveguide in the vertical direction.

4. The semiconductor package of claim 1, wherein a portion of the optical waveguide is under the interposer in the vertical direction.

5. The semiconductor package of claim 1, further comprising a transparent encapsulation material between the first semiconductor chip and the interposer.

6. The semiconductor package of claim 5, wherein the transparent encapsulation material is between the optical waveguide and the interposer.

7. The semiconductor package of claim 1, wherein the first semiconductor chip comprises an active surface and an inactive surface,
wherein the photonic integrated circuit is on the active surface, and
wherein the first semiconductor chip is inside the cavity such that the active surface faces the interposer.

8. The semiconductor package of claim 7, wherein the first semiconductor chip further comprises a plurality of connection pads electrically connecting the first semiconductor chip to the interposer, and
wherein the plurality of connection pads are on the active surface.

9. The semiconductor package of claim 8, wherein at least some of the plurality of connection pads do not overlap the second semiconductor chip in the vertical direction.

10. The semiconductor package of claim 1, wherein the cavity is separated from a side surface of the printed circuit board.

11. The semiconductor package of claim 1, wherein the first semiconductor chip is configured to convert an optical signal received from the optical waveguide into an electrical signal and transfer the electrical signal to the second semiconductor chip through the interposer.

12. The semiconductor package of claim 1, further comprising a through via penetrating into the interposer,
wherein the interposer comprises glass.

13. The semiconductor package of claim 1, further comprising a redistribution structure on at least one of an upper surface of the interposer or a lower surface of the interposer.

14. A semiconductor package comprising:
a main printed circuit board defining at least one cavity extending inward from an upper surface thereof;
a plurality of main optical waveguides extending above the at least one cavity from the upper surface of the printed circuit board;
a plurality of first semiconductor chips positioned inside the at least one cavity to each overlap a portion of one of the plurality of main optical waveguides in a vertical direction and comprising an active surface and an inactive surface;
an interposer on the plurality of first semiconductor chips; and
a second semiconductor chip on the interposer,
wherein the interposer overlaps at least a portion of each of the plurality of first semiconductor chips in the vertical direction, and the plurality of first semiconductor chips are mounted inside the at least one cavity such that the active surface faces the interposer.

15. The semiconductor package of claim 14, further comprising:
a sub-printed circuit board on the upper surface of the main printed circuit board;
a sub-optical waveguide on an upper surface of the sub-printed circuit board; and
a third semiconductor chip on the sub-printed circuit board and the sub-optical waveguide and electrically connected to the sub-printed circuit board,
wherein the third semiconductor chip is configured to convert an optical signal received from the sub-optical waveguide into an electrical signal and transfer the electrical signal to the second semiconductor chip through the sub-printed circuit board, the main printed circuit board, and the interposer.

16. The semiconductor package of claim 15, wherein the sub-optical waveguide is between the sub-printed circuit board and the third semiconductor chip in the vertical direction, and wherein the main printed circuit board and the plurality of first semiconductor chips are under the plurality of main optical waveguides in the vertical direction.

17. The semiconductor package of claim 14, wherein there are a first cavity and a second cavity in the main printed circuit board, and the first cavity and the second cavity are arranged in a zigzag manner along one edge of the main printed circuit board.

18. The semiconductor package of claim 14, wherein at least two first semiconductor chips are inside a cavity of the main printed circuit board.

19. A semiconductor package comprising:
a printed circuit board with a cavity extending inward from an upper surface thereof;
an optical waveguide extending above the cavity from the upper surface of the printed circuit board;
a first semiconductor chip positioned inside the cavity and comprising a photonic integrated circuit overlapping a portion of the optical waveguide above the cavity in a vertical direction;
an interposer on the first semiconductor chip; and
a second semiconductor chip on the interposer,
wherein the photonic integrated circuit comprises a light-receiving section configured to receive an optical signal discharged from the optical waveguide and is configured to convert the optical signal into an electrical signal, the first semiconductor chip is inside the cavity such that the photonic integrated circuit is separated from a bottom surface of the cavity, and at least a portion of the optical waveguide is between the interposer and the first semiconductor chip.

20. The semiconductor package of claim 19, wherein the interposer comprises a glass substrate and a through via penetrating into the glass substrate, the wherein first semiconductor chip is inside the cavity such that an active surface of the first semiconductor chip faces the interposer, and the cavity is separated from an edge of the printed circuit board.
